(19) United States
(12) Patent Application Publication
(10) Pub. No.: US 2024/0224541 A1
(43) Pub. Date: Jul. 4, 2024

(54) 3D PHASE CHANGE MEMORY AND METHOD OF MANUFACTURING THE SAME

(71) Applicant: Powerchip Semiconductor Manufacturing Corporation, HSINCHU (TW)

(72) Inventor: Zih-Song Wang, Nantou County (TW)

(73) Assignee: Powerchip Semiconductor Manufacturing Corporation, HSINCHU (TW)

(21) Appl. No.: 18/119,838

(22) Filed: Mar. 10, 2023

(30) Foreign Application Priority Data
Jan. 4, 2023 (TW) 112100207

(51) Int. Cl. H10B 63/00; H10B 63/10

(52) U.S. Cl. CPC H10B 63/845; H10B 63/10; H10B 63/24

(57) ABSTRACT

A 3D phase change memory (PCM) is provided in the present invention, including a layer stack consisted of multiple alternate first layers and second layers, a trench vertically extending through the layer stack and each second layers recessed in a horizontal first direction to form a lateral recess, multiple top electrodes filling up the lateral recesses, two ovonic threshold switch (OTS) layers respectively on two sidewalls of the trench, multiple phase change layers on two sidewalls of the two OTS layers, multiple bottom electrodes filling up the trench, and multiple holes vertically extending to the surface of layer stack and the holes divide the bottom electrodes and divide the phase change layers in a horizontal second direction, wherein the second direction is perpendicular to the first direction.

### BACKGROUND OF THE INVENTION

### 1. Field of the Invention

The present invention relates generally to a phase change memory, and more specifically, to a vertical 3D XPoint phase change memory and method of manufacturing the same.

### 2. Description of the Prior Art

Storage class memory (SCM) is one of trending storage technologies in recent years, featuring high-speed access performance with latency between dynamic random access memory (DRAM) and Flash memory and non-volatile data storage function, which may effectively solve problem of large latency gaps between storage levels in memory hierarchy of current data processing architecture, especially the latency gap between DRAM and solid-state drive (SSD) (may be up to a thousand times), without inherent disadvantages of power consumption and data loss in non-volatile memory like DRAM.

There are several kinds of emerging memory nowadays suitable for storage class memory, including resistive-based memory like magnetoresistive random access memory (MRAM), phase change memory (PCM), resistive random-access memory (ReRAM), or charge-trapping based memory like 3D NOR or 3D NAND of single-level cell (SLC), wherein phase change memory is the only storage class memory suitable in every aspect of the application in the field of artificial internet of things (AIoT), including functioning as a S-type SSD or M-type processing-in-memory (PIM), which has substantial development potential in the future.

Nevertheless, current phase change memory is mostly in planar Xpoint architecture similar to conventional NAND memory with limited storage density. In addition, although the phase change memory designed in 3D NAND architecture may significantly increase storage density, relevant process is very complicated due to their multilayered features (may include up to 5-7 levels), especially in the process involved atomic-level film deposition with fairly expensive process cost. In another aspect, it becomes more and more difficult to form through-holes with uniform aspect ratio when the layer number of layer stack in 3D memory architecture gets higher and higher. Accordingly, those of ordinarily skilled in the art are urged to improve the structure and process of current phase change memory, in order to solve aforementioned disadvantages.

### SUMMARY OF THE INVENTION

In light of the aforementioned disadvantages in conventional skills, the present invention hereby provides a novel 3D phase change memory (PCM), with feature of forming memory units through trenches rather than through holes, so that atomic-level deposition process is required only in the step of forming bottom electrode portion, thereby significantly reducing production cost and time, fulfilling the mass production and application of phase change memory in the field of storage class memory (SCM).

One aspect of the present invention is to provide a 3D phase change memory, including structures of: a substrate; a layer stack on the substrate and consisted of multiple alternate first layers and second layers; a trench extending from the substrate through entire layer stack in a direction vertical to the substrate and each second layer recessed in a horizontal first direction from the trench to form a lateral recess; multiple adhesive layers, each adhesive layer is on a surface of one lateral recess; multiple top electrodes, each top electrode is on one adhesive layer and fills up one lateral recess; two ovonic threshold switch (OTS) layers respectively on two sidewalls of the trench in the first direction; multiple phase change layers on two sidewalls of the two OTS layers in the first direction; multiple bottom electrodes between the phase change layers and filling up the trench; and multiple holes extending from the substrate to a surface of the layer stack in the vertical direction, wherein these holes divide the bottom electrodes and divide the phase change layers, and these holes extend in the first direction to the two OTS layers at two sides.

Another aspect of the present invention is to provide a 3D phase change memory, including structures of: a substrate; a layer stack on the substrate and consisted of multiple alternate first layers and top electrode layers; a trench extending from the substrate through entire layer stack in a direction vertical to the substrate and each top electrode layer recessed in a horizontal first direction from the trench to form a lateral recess; multiple ovonic threshold switch (OTS) layers, each OTS layer fills up one lateral recess; phase change layers on sidewalls of the trench in the first direction; multiple bottom electrodes between the phase change layers and filling up the trench; and multiple holes extending from the substrate to a surface of the layer stack in the vertical direction, wherein these holes divide the bottom electrodes and divide the phase change layers, and these holes extend in the first direction to the OTS layers at two sides.

Still another aspect of the present invention is to provide a method of manufacturing a 3D phase change memory, including steps of: providing a substrate; forming multiple alternate first layers and second layers on the substrate to constitute a layer stack; performing a first photolithography process to form a trench in the layer stack, the trench extends from the substrate in a direction vertical to the substrate through entire layer stack; performing an etching process to remove parts of the second layers exposed from the trench, so that each second layer is recessed in a horizontal first direction from the trench to form a lateral recess; forming an adhesive layer on a surface of each lateral recess; forming a top electrode on each adhesive layer, each top electrode fills up one lateral recess; forming an ovonic threshold switch (OTS) layer and a phase change layer sequentially on two sidewalls of the trench in the first direction; forming a bottom electrode filling up the trench; and performing a second photolithography process to form multiple holes extending in the vertical direction from the substrate to a surface of the layer stack, these holes divide the bottom electrodes and divide the phase change layers, and these holes extend in the first direction to the two OTS layers at two sides.

Still another aspect of the present invention is to provide a method of manufacturing a 3D phase change memory, including steps of: providing a substrate; forming multiple alternate first layers and second layers on the substrate to constitute a layer stack; performing a first photolithography process to form a trench in the layer stack, the trench extends from the substrate in a direction vertical to the substrate through entire layer stack; performing an etching process to remove parts of the second layers exposed from the trench, so that each top electrode layer is recessed in a horizontal first direction from the trench to form a lateral recess; forming an ovonic threshold switch (OTS) layer in each lateral recess, each OTS layer fills up one lateral recess; forming a phase change layer on two sidewalls of the trench in the first direction; forming a bottom electrode filling up the trench; and performing a second photolithography process to form multiple holes extending in the vertical direction from the substrate to a surface of the layer stack, these holes divide the phase change layer into multiple phase change layers and divide the bottom electrode into multiple bottom electrodes, and these holes extend in the first direction to the OTS layers at two sides.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of a 3D phase change memory in accordance with one embodiment of present invention;

FIG. 2 to FIG. 7 are schematic cross-sectional views illustrating a process flow of manufacturing a 3D phase change memory in accordance with one embodiment of present invention;

FIG. 8 and FIG. 13 are schematic top views of a 3D phase change memory in accordance with another embodiment of present invention;

FIG. 9 to FIG. 12, FIG. 14 and FIG. 16 to FIG. 19 are schematic cross-sectional views illustrating a process flow of manufacturing a 3D phase change memory in accordance with one embodiment of present invention; and

FIG. 15 is a schematic top view of a 3D phase change memory in accordance with one embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element (s) or feature (s) as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

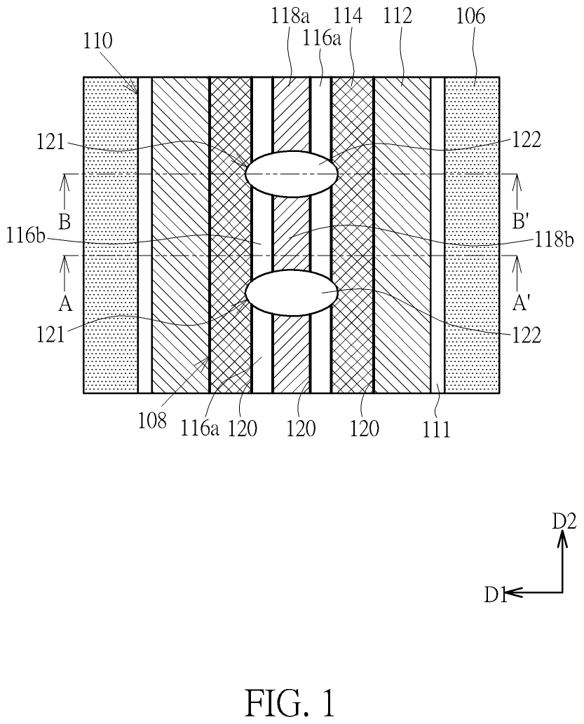

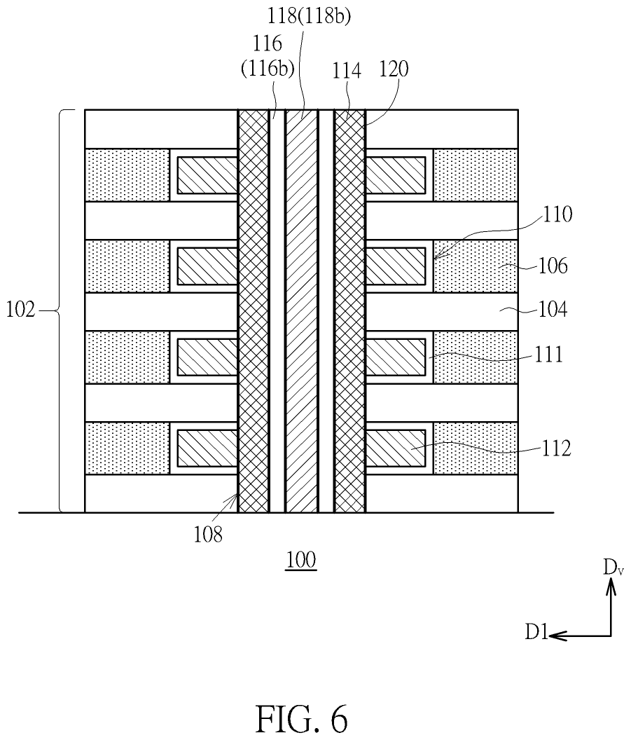

Please refer collectively to FIG. 1 and FIG. 6, which are schematic top view and cross-sectional view of a 3D phase change memory in accordance with one embodiment of the present invention, wherein the plane shown in FIG. 1 is a horizontal cross-section with top electrodes 112, and FIG. 6 is a schematic cross-sectional view taken along the section line A-A′ in FIG. 1, in order to provide readers a better understanding of relative positions and connections of main components in the layout and layer structures of the phase change memory of present invention. The phase change memory of present invention is in a form of 3D Xpoint architecture, and the positions where multilayered word lines and vertical bit lines intersect are memory units.

The 3D phase change memory of present invention is constituted on a substrate 100. The material of substrate 100 is preferably a silicon substrate, for example a p-type doped silicon substrate. Other silicon-containing substrate may also be adopted in the present invention, including Group III-V-on-silicon (ex. GaN-on-silicon) substrate, silicon-on-insulator (SOI) substrate or substrate of other doping type, but not limited thereto. In other embodiment, the substrate 100 may be one of inter-metal dielectric (IMD) layer in semiconductor back-end-of-line (BEOL) process. A layer stack 102 is formed on the substrate 100, which is consisted of multiple alternate first layers 104 and second layers 106. The layer number in the layer stack may be several hundred in order to increase the number of storage cells. In the embodiment, the material of first layer 104 and second layer 106 may be silicon oxide and polysilicon respectively, or silicon oxide and silicon nitride respectively. The materials of these two layers are electrically insulating and provided with distinct etching selectivity. A trench 108 extends in a vertical direction D_{V} vertical to the substrate from the substrate 100 through entire layer stack 102 and extends in a horizontal second direction D2. Furthermore, each second layer 106 is recessed from the trench 108 in a horizontal first direction D1 to form a lateral recess 110. The first direction D1 is preferably perpendicular to the second direction D2. In this way, a trench 108 and multiple lateral recesses 110 extending from two sides of the trench 108 and alternated with the first layers 104 in different levels are formed in the layer stack 102.

Refer still to FIG. 1 and FIG. 6. A conformal adhesive layer 111 is formed on the surface of each lateral recess 110, which may be formed of electrically conductive material. Other space of each lateral recess 110 is filled up with a top electrode 112. The material of top electrode 112 may be material with good electrical conductivity, ex. tungsten (W), copper (Cu), aluminum (Al) or the alloy thereof. In the embodiment of present invention, the top electrodes 112 are word lines of phase change memory, which are in different levels and isolated by electrically insulating first layers 104. With this design, in the embodiment of present invention, multiple word lines 112 are in two sidewalls of the trench 108 in the first direction D1, which are in different levels and extend in the same second direction D2 as the trench 108. The word lines 112 extending out of the stack may form a staircase structure to be connected with external circuits above through contacts formed thereon (not shown). Preferably, lateral surfaces of these top electrodes 112, adhesive layers 111 and first layers 104 in the first direction D1 are flush.

Refer still to FIG. 1 and FIG. 6. an ovonic threshold switch (OTS) layer 114 and multiple phase change layers 116a, 116b are formed sequentially on two sidewalls of the trench 108 in the first direction D1. The OTS layer 114 functions as a selector for the phase change memory, which covers on the sidewall constituted by the first layers 104 and the top electrodes 112 and is connected directly therewith. The material of OTS layer 114 may be amorphous chalcogenide, ex. Se-doped germanium (GeTe), with properties of high selectivity, high switching speed and ovonic operation, etc., and is not crystallized in operating temperature of the phase change memory. The phase change layers 116a, 116b are storage cells of the phase change memory. In the embodiment of present invention, multiple phase change layers 116a, 116b are formed on sidewalls of the OTS layers 114 and are isolated and alternated in the second direction D2. The phase change layers 116a, 116b are odd memory units and even memory units of the phase change memory respectively, whose material may be germanium-antimony-tellurium (GeSbTe-based, GST) alloy, ex. N-doped GeSbTe, Sb₂Te, GeSb or In-doped Sb₂Te, with stable structure and resistance and high crystallization rate, which will be crystallized at operating temperature of the phase change memory and alters their resistance, thereby achieving the mechanism of resistive storage.

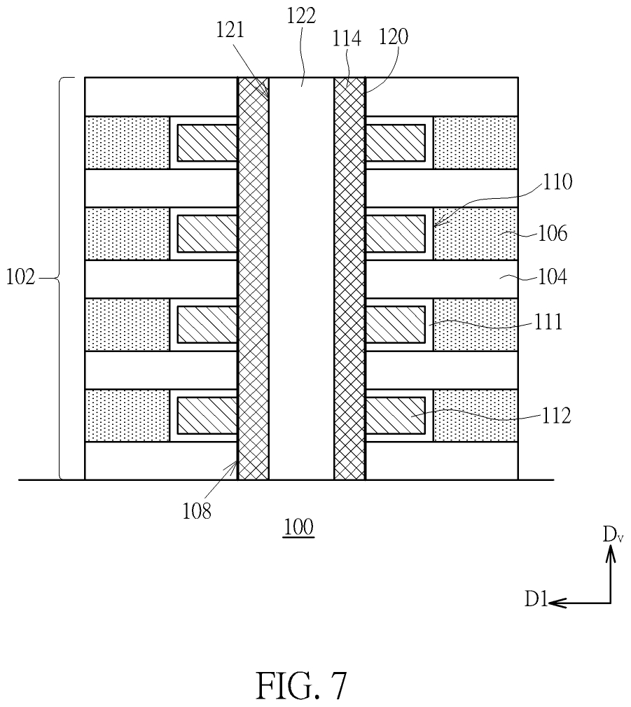

Refer still to FIG. 1 and FIG. 6. Multiple bottom electrodes 118a, 118b are between the phase change layers 116a, 116b at two sides and fill up the trench 108. In the embodiment of present invention, the bottom electrodes 118a, 118b are odd bit lines and even bit lines of the phase change memory respectively, which are in a column form extending in the vertical direction D_{V} from the substrate 100 to the surface of layer stack 102, and are isolated and alternated in the second direction D2. In read operation, the bottom electrodes 118a, 118b are functioned to detect the resistances of corresponding phase change layers 116a, 116b at two sides, in order to obtain their storage states, ex. 0-bit or 1-bit. Moreover, in the embodiment of present invention, multiple holes 121 are further formed in the layer stack 102 as shown in FIG. 7 (cross-section view taken along the section line B-B′ in FIG. 1), which extend in the vertical direction D_{V} from the substrate 100 to the surface of layer stack 102. In the embodiment of present invention, the holes 121 are components isolating the bottom electrodes 118a, 118b and isolating phase change layers 116a, 116b. The holes 121 extend in the first direction D1 to the OTS layers 114 at two sides and are spaced-apart and aligned in the second direction D2, thereby isolating multiple bottom electrodes 118a, 118b and multiple phase change layer 116a, 116b. In other embodiment, the holes 121 may be further filled with insulating material, ex. silicon oxide, to form isolating structures 122, which may also isolate those bottom electrodes 118a, 118b and isolate those phase change layers 116a, 116b.

Refer still to FIG. 1 and FIG. 6. In addition to the aforementioned components, in the embodiment of present invention, heating layers 120 may be further formed between the top electrodes 112 and the OTS layers 114, or between the OTS layers 114 and the phase change layers 116a, 116b, or between the phase change layers 116a, 116b and the bottom electrodes 118a, 118b. The function of heating layers 120 is to heat the OTS layers 114 and the phase change layers 116a, 116b, so that the phase change layers 116a, 116b may be phase-changed to achieve the storage operation of memory. The material of heating layer 120 may be material with excellent thermal conductivity, ex. amorphous carbon (σ-C), titanium nitride (TiN), titanium oxynitride (TiNₓO_{y}), tantalum nitride (TaN) or titanium aluminum nitride (TiAlN).

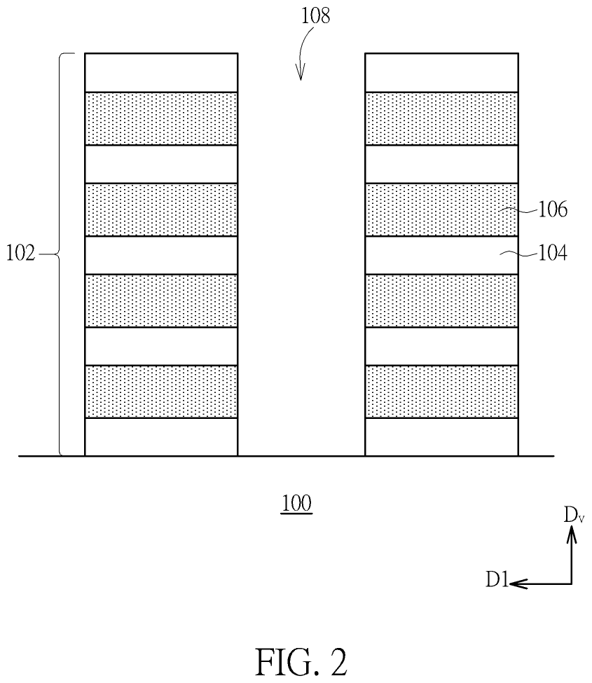

Next, please refer to FIG. 2 to FIG. 7 sequentially, which illustrates a process flow of manufacturing the 3D phase change memory in aforementioned embodiment of present invention.

Please refer to FIG. 2. First, provide a substrate 100. The material of substrate 100 is preferably a silicon substrate, for example a p-type doped silicon substrate. Other silicon-containing substrate may also be adopted in the present invention, including Group III-V-on-silicon (ex. GaN-on-silicon) substrate, SOI substrate or substrate of other doping type, but not limited thereto. In other embodiment, the substrate 100 may be one of IMD layers in semiconductor BEOL process. Thereafter, multiple first layers 104 and second layers 106 are formed alternately on the substrate 100 to constitute a layer stack 102. The material of first layer 104 and second layer 106 may be silicon oxide and polysilicon respectively, or silicon oxide and silicon nitride respectively, which may be formed through deposition process like chemical vapor deposition (CVD) or atomic layer deposition (ALD). After the layer stack 102 is formed, a photolithography process is then performed to form a trench 108 in the layer stack 102, which extends in the vertical direction D_{V} from the substrate 100 through entire layer stack 102. Please note that, in comparison to conventional skills that use through hole features, the approach of forming trench feature is easier to achieve uniform aspect ratio, so that the resulting memory units would have better electrical property, which is one of advantages of the present invention.

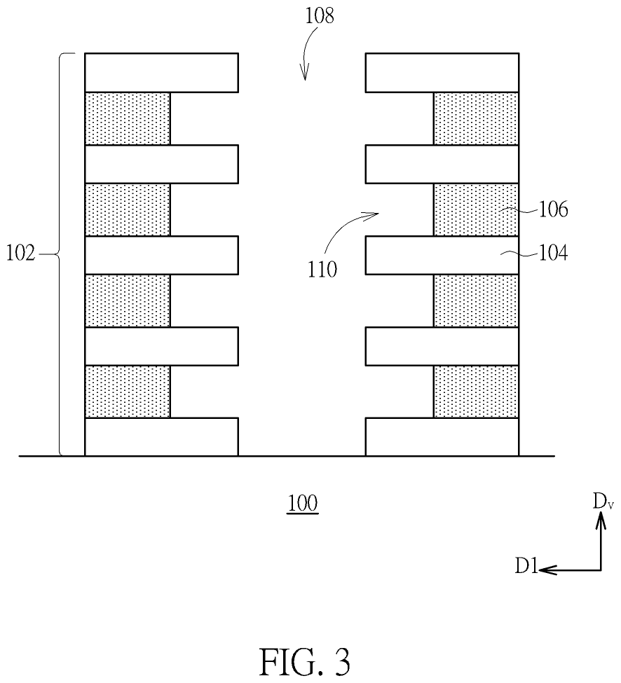

Please refer to FIG. 3. After the trench 108 is formed, a selective etching process is performed to remove parts of the second layers 106 exposed from the trench 108, while the first layers 104 are not removed in this process, so that each second layer 106 is recessed from the trench 108 in the horizontal first direction D1 to form a lateral recess 110. The lateral recesses 110 extend from the trench 108 and are alternated with the first layers 104 in different levels of the layer stack.

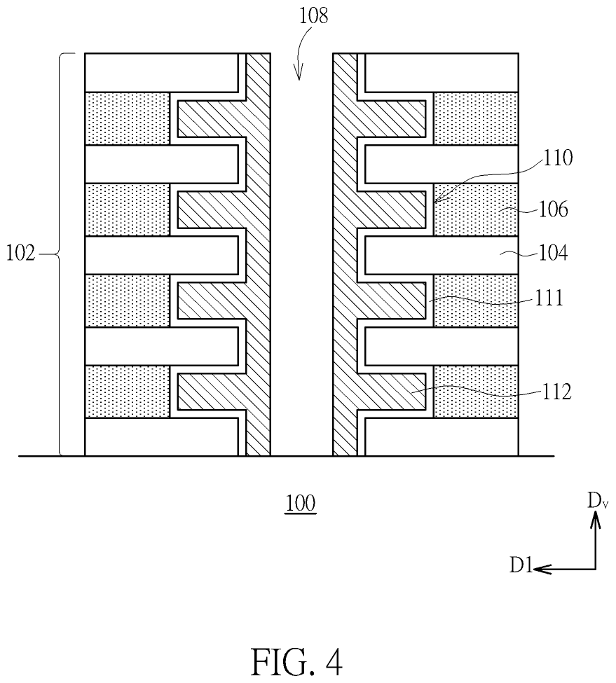

Please refer to FIG. 4. After the lateral recesses 110 are formed, conformal adhesive layers and top electrode layers 112 are formed sequentially on surfaces of the lateral recesses 110 and lateral sides of the first layers 104 at two sides of the trench 108 in the first direction D1. Each top electrode layer 112 fills up and covers the lateral recesses 110 at one side of the trench 108. In the embodiment of present invention, the material of adhesive layer 111 may be silicon oxide, and the material of top electrode layer 112 may be metal like W, Cu, Al or the alloy thereof, both of them may be formed through the process like CVD, physical vapor deposition (PVD) or ALD. The trench 108 still remains after the adhesive layers 111 and the top electrode layers 112 are formed.

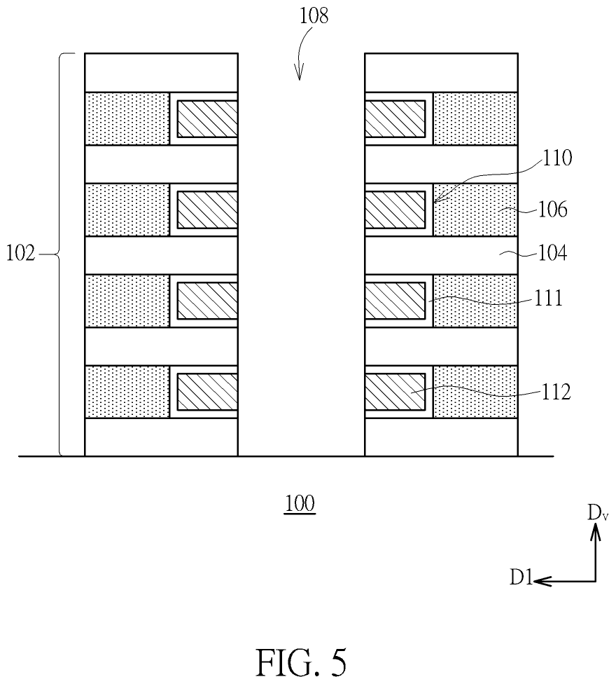

Please refer to FIG. 5. After adhesive layers 111 and top electrode layers 112 are formed, a lateral etching process is then performed to laterally remove parts of the two top electrode layers 112 and two adhesive layers 111 at two sides of the trench 108 until the first layers 104 are exposed, thereby forming the adhesive layers 111 only on the surfaces of lateral recesses 110 and the top electrodes 112 filling up the lateral recesses 110 on the adhesive layers 111. The sidewalls of these top electrodes 112, adhesive layers 111 and first layers 104 in the first direction D1 are preferably flush due to this process.

Please refer to FIG. 6. OST layers 114 and phase change layers 116 are then formed sequentially on two sidewalls of the trench 108 in the first direction D1, and remaining space in the trench 108 is filled up with a bottom electrode 118. Steps of forming the OST layers 114 and the phase change layers 116 may include forming a conformal OST layer 114 and a conformal phase change layer 116 sequentially on two sidewalls of the trench 108, on a surface of substrate 100 and on a surface of layer stack 102, and an anisotropic etching process is then performed to remove the OST layer 114 and phase change layer 116 on the horizontal plane, so that the layer stack 102 and substrate 100 are exposed and two OTS layers 114 and two phase change layers 116 remain on the two sidewalls of trench 108. In the embodiment of present invention, the material of OTS layer 114 may be amorphous chalcogenide, ex. Se-doped GeTe. The material of phase change layer 116 may be GeSbTe-based alloy (GST), ex. N-doped GeSbTe, Sb₂Te, GeSb or In-doped Sb₂Te. Both of them may be formed through process like CVD, PVD and ALD. The material of bottom electrode 118 may be the same as the one of top electrode 112, ex. W, Cu, Al or the alloy thereof, which may be formed through ALD. In comparison to conventional skills, please note that in this process the present invention adopts trench feature rather than through-hole feature to form memory units, it is easier to maintain uniform aspect ratio of film deposition, so that costly atomic-level deposition process is required only in the step of forming bottom electrode portion, thereby significantly reducing production cost and time, fulfilling the mass production and application of phase change memory in the field of storage class memory (SCM).

Lastly, please refer collectively to FIG. 1 and FIG. 7. After the OTS layers 114, the phase change layers 116 and the bottom electrodes 118 are formed, a photolithography process is then performed to form multiple holes 121 in the layer stack 102. The holes 121 extend from substrate 110 to the surface of layer stack 102 in a vertical direction D_{V} through parts of phase change layers 116 and bottom electrodes 118, and these holes 121 also extend in the first direction D1 to the OTS layers 114 at two sides. In this way, the holes 121 divide original phase change layer 116 and bottom electrode 118 into multiple phase change layers 116a, 116b and multiple bottom electrodes 118a, 118b, wherein phase change layers 116a, 116b are odd memory units and even memory units of the 3D phase change memory respectively, while bottom electrodes 118a, 118b are odd bit lines and even bit lines of the 3D phase change memory respectively. In addition, the holes 121 may be further filled with insulating material, ex. silicon oxide, to form isolation structures 122 for isolating the bottom electrodes 118a, 118b and phase change layers 116a, 116b.

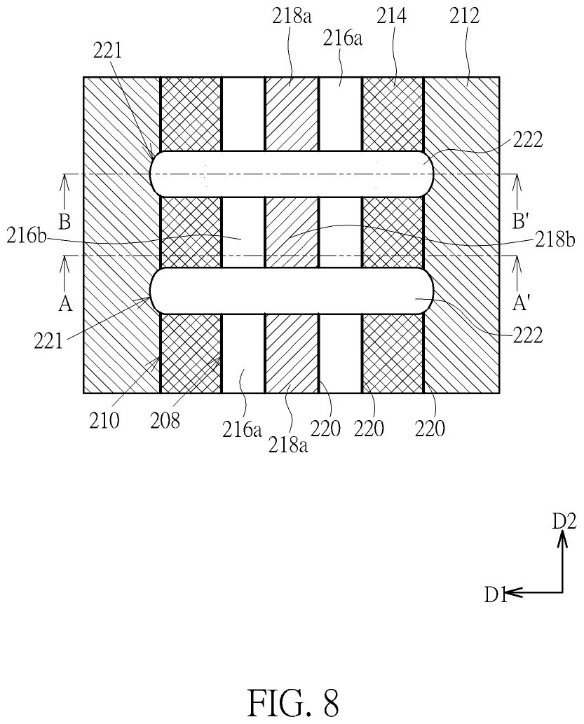

Please refer collectively to FIG. 8 and FIG. 18, which are schematic top view and cross-sectional view of a 3D phase change memory in accordance with another embodiment of the present invention, wherein the plane shown in FIG. 8 is a horizontal cross-section with top electrodes 212, and FIG. 18 is a schematic cross-sectional view taken along the section line A-A′ in FIG. 8, in order to provide readers a better understanding of relative positions and connections of main components in the layout and layer structures of the phase change memory in the present invention. The main difference between this embodiment and aforementioned embodiment is that the lateral recesses 210 in this embodiment are filled with ovonic threshold switch (OTS) layers 214, while the top electrodes 212 replace the second layers 206 in original layer stack 202 in the end of process.

First, the 3D phase change memory is constituted on a substrate 200. The material of substrate 200 is preferably a silicon substrate, for example a p-type doped silicon substrate. Other silicon-containing substrate may also be adopted in the present invention, including Group III-V-on-silicon (ex. GaN-on-silicon) substrate, SOI substrate or substrate of other doping type, but not limited thereto. In other embodiment, the substrate 200 may be one of IMD layers in semiconductor BEOL process. A layer stack 202 is formed on the substrate 200, which is consisted of multiple alternate first layers 204 and top electrode layers 212. The layer number in the layer stack may be several hundred, in order to increase the number of storage cells. In the embodiment, the material of first layer 204 may be silicon oxide, and the material of top electrode layer 212 may be metal like W, Cu, Al or the alloy thereof. In the embodiment of present invention, the top electrode layers 212 are word lines of the phase change memory, which are set in different levels and isolated by electrically insulating first layers 204. The word lines 212 extending out of the layer stack may form a staircase structure to be connected with external circuits above through contacts formed thereon (not shown).

Refer still to FIG. 8 and FIG. 18. A trench 208 extends from the substrate 200 in a direction D_{V} vertical to the substrate through entire layer stack 202 and extends in a horizontal second direction D2. Furthermore, each top electrode layer 212 is recessed from the trench 208 in a horizontal first direction D1 to form a lateral recess 210. The first direction D1 is preferably perpendicular to the second direction D2. In this way, a trench 208 and multiple lateral recesses 210 extending from two sides of the trench 208 and alternated with the first layers 204 in different levels are formed in the layer stack 202. The space of each lateral recess 210 is filled up with an OTS layer 214. The OTS layer 214 functions as a selector for the phase change memory, with material of amorphous chalcogenide, ex. Se-doped GeTe, with property of high selectivity, high switching speed and ovonic operation and will not be crystallized at operating temperature of the phase change memory. Preferably, the lateral surfaces of these OTS layers 214 and first layers 204 in the first direction D1 are flush. With this arrangement, in the embodiment of present invention, two sidewalls of the trench 208 in the first direction D1 is constituted by the OTS layers 214 and the first layers 204, and the OTS layers 214 are in different levels of the layer stack 202 and also horizontally extend in the same second direction D2 as trench 208.

Refer still to FIG. 8 and FIG. 18. Multiple phase change layers 216a, 216b are formed on two sidewalls of the trench 208 in the first direction D1 to function as odd memory units and even memory units of the phase change memory. In the embodiment of present invention, multiple phase change layers 216a, 216b are formed on the sidewall of OTS layer 214 and are isolated alternately in the second direction D2. The material of phase change layers 216a, 216b may be GeSbTe-based alloy, ex. N-doped GeSbTe, Sb₂Te, GeSb or In-doped Sb₂Te, with stable structure and resistance and high crystallization rate. These materials will be crystallized at operating temperature of the phase change memory and their resistances will be altered, thereby achieving the mechanism of resistive storage.

Refer still to FIG. 8 and FIG. 18. Multiple bottom electrodes 218a, 218b are between the phase change layers 216a, 216b of odd/even memory units respectively and fill up the trench 208. In the embodiment of present invention, the bottom electrodes 218a, 218b are odd bit lines and even bit lines of the 3D phase change memory respectively, which is in a columnar form extending in a vertical direction D_{V} from the substrate 200 to the surface of layer stack 202, and are isolated alternately in the second direction D2. In read operation, the bottom electrodes 218a, 218b are functioned to detect the resistances of corresponding phase change layers 216a, 216b at two sides in order to obtain their storage states, such as 0-bit or 1-bit. Moreover, in the embodiment of present invention, multiple holes 221 are further formed in the layer stack 202 as shown in FIG. 14 (cross-section view taken along the section line B-B′ in FIG. 8), which extend in the vertical direction D_{V} from the substrate 200 to the surface of layer stack 202. In the embodiment of present invention, the holes 221 are feature isolating the bottom electrodes 218a, 218b and isolating the phase change layers 216a, 216b. The holes 221 extend in the first direction D1 to the top electrode layers 212 at two sides through the OTS layers 214 and are spaced-apart and aligned in the second direction D2, so as isolating multiple bottom electrodes 218a, 218b and phase change layer 216a, 216b. In other embodiment, the holes 221 may be further filled with insulating material, ex. silicon oxide, to form isolating structures 222, which may also isolate those bottom electrodes 218a, 218b and isolate those phase change layers 216a, 216b. In addition, although the holes 221 in FIG. 8 extend to the top electrode layer 212, in other embodiment, they may extend merely to OTS layers 214, as long as the bottom electrodes 218a, 218b and phase change layers 216a, 216b are isolated by the holes 221.

Refer still to FIG. 8 and FIG. 18. In addition to the aforementioned components, in the embodiment of present invention, heating layers 220 may be further formed between the top electrodes 212 and OTS layers 214, or between the OTS layers 214 and phase change layers 216a, 216b, or between the phase change layers 216a, 216b and bottom electrodes 218a, 218b. The function of heating layers 220 is to heat the OTS layers 214 and the phase change layers 216a, 216b, so that phase change layers 216a, 216b among them may be phase-changed to achieve storage operation of the memory. The material of heating layer 220 may be material with excellent thermal conductivity, ex. amorphous carbon (σ-C), TiN, TiNₓO_{y}, TAN or TiAlN.

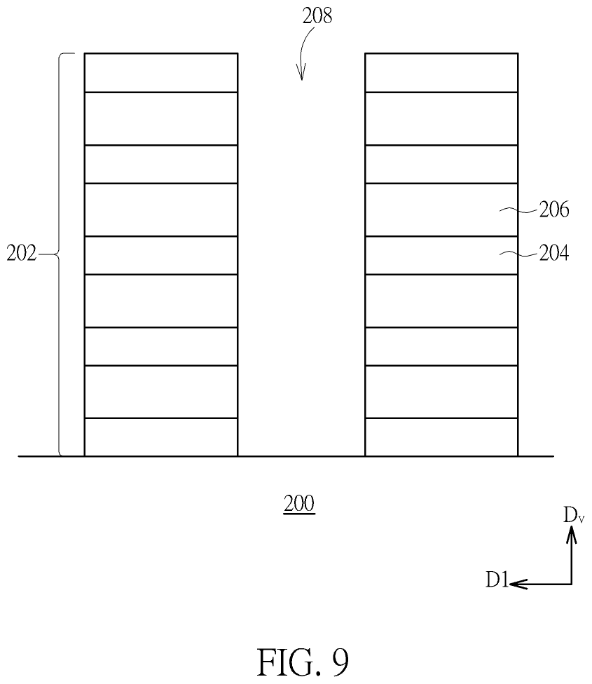

Please refer sequentially to FIG. 9 to FIG. 12, which illustrates a process flow of manufacturing the 3D phase change memory in aforementioned embodiment of present invention.

Please refer to FIG. 9. First, provide a substrate 200. The material of substrate 200 is preferably a silicon substrate, for example a p-type doped silicon substrate. Other silicon-containing substrate may also be adopted in the present invention, including Group III-V-on-silicon (ex. GaN-on-silicon) substrate, SOI substrate or substrate of other doping type, but not limited thereto. In other embodiment, the substrate 200 may be one of IMD layers in semiconductor BEOL process. Next, multiple first layers 204 and second layers 206 are formed alternately on the substrate 200 to constitute a layer stack 202. The material of first layer 204 may be silicon oxide, the material of second layer 206 may be silicon nitride, both of them may be formed through deposition process like CVD, PVD or ALD and are provided with distinct etching selectivity in specific etching process. After the layer stack 202 is formed, a photolithography process is then performed to form a trench 208 in the layer stack 202, which extends in the vertical direction D_{V} from the substrate 200 through entire layer stack 202 and also extend in the horizontal second direction D2. In comparison to conventional skills that form through-hole features, please note that the approach of forming trench feature is easier to achieve uniform aspect ratio, which is one of the advantages in the present invention.

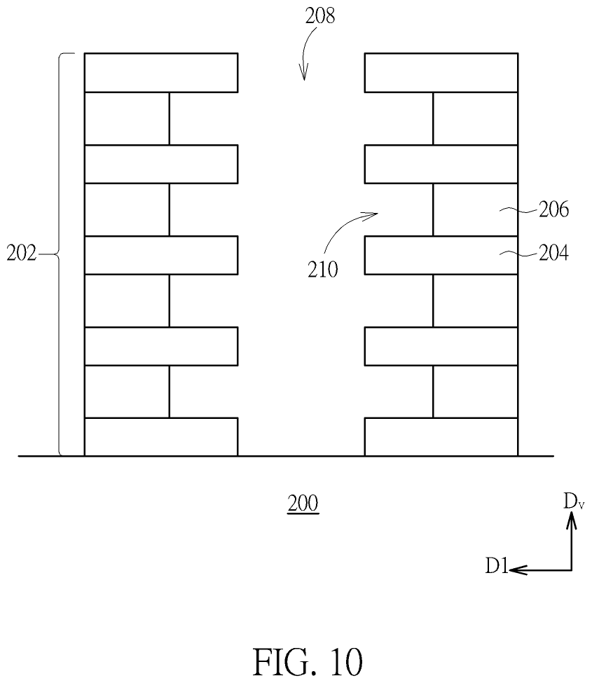

Please refer to FIG. 10. After the trench 208 is formed, a selective etching process is performed to remove parts of the second layers 206 exposed from the trench 208, while the first layers 204 are not removed in this process, so that each second layer 206 is recessed from the trench 208 in the horizontal first direction D1 to form a lateral recess 210. The lateral recesses 210 extend from two sides of the trench 208 and are alternated with the first layers 204 in different levels of the layer stack 202.

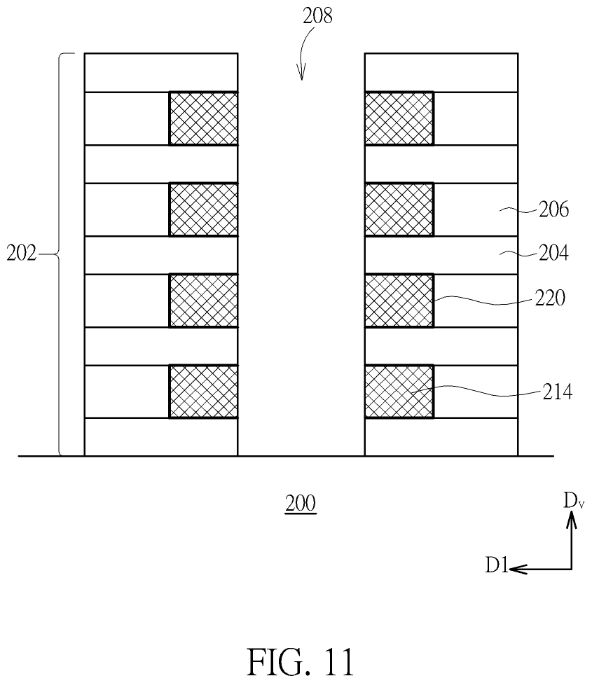

Please refer to FIG. 11. After the lateral recesses 210 are formed, OTS layers 214 are formed in the lateral recesses 210 at two sides of trench 208 in the first direction D1. The OTS layers 214 may be formed by first forming an OTS layer 214 in the lateral recesses 210 and on sidewalls of the first layers 204, and a lateral etching process is then performed to laterally remove parts of the OTS layers 214 at two sides of the trench 208 until the first layers 204 are exposed, thereby forming the OTS layers 214 only in the lateral recesses 210. The sidewalls of OTS layers 214 and first layers 204 in the first direction D1 are preferably flush due to this process. In the embodiment of present invention, the material of OTS layers 214 may be amorphous chalcogenide, ex. Se-doped GeTe, which may be formed through the process like CVD, PVD and ALD.

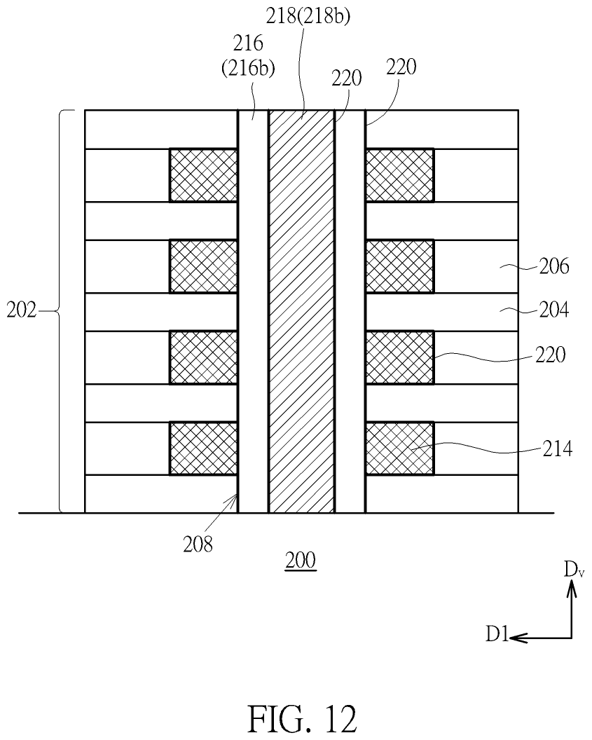

Please refer to FIG. 12. Phase change layers 216 are then formed respectively on two sidewalls of the trench 208 in the first direction D1, and remaining space in the trench 208 between the two sidewalls is filled up with a bottom electrode 218. Steps of forming the phase change layer 216 may include forming conformal phase change layer 216 on two sidewalls of the trench 208, on the surface of substrate 200 and on the surface of layer stack 202, and an anisotropic etching process is then performed to remove the phase change layer 216 on the horizontal plane, so that the layer stack 202 and substrate 200 are exposed and the two phase change layers 216 remain on the two sidewalls of trench 208. In the embodiment of present invention, the material of phase change layer 216 may be GeSbTe-based alloy (GST), ex. N-doped GeSbTe, Sb₂Te, GeSb or In-doped Sb₂Te, which may be formed through process like PVD or ALD. Material of the bottom electrode 218 may be metal like W, Cu, Al or the alloy thereof, which may be formed through ALD. In comparison to conventional skills, please note that the present invention adopts trench feature rather than through-hole feature to form memory units, it is easier to maintain uniform aspect ratio of film deposition, so that costly atomic-level deposition process is required only in the step of forming bottom electrode portion, thereby significantly reducing production cost and time, fulfilling the mass production and application of phase change memory in the field of storage class memory (SCM).

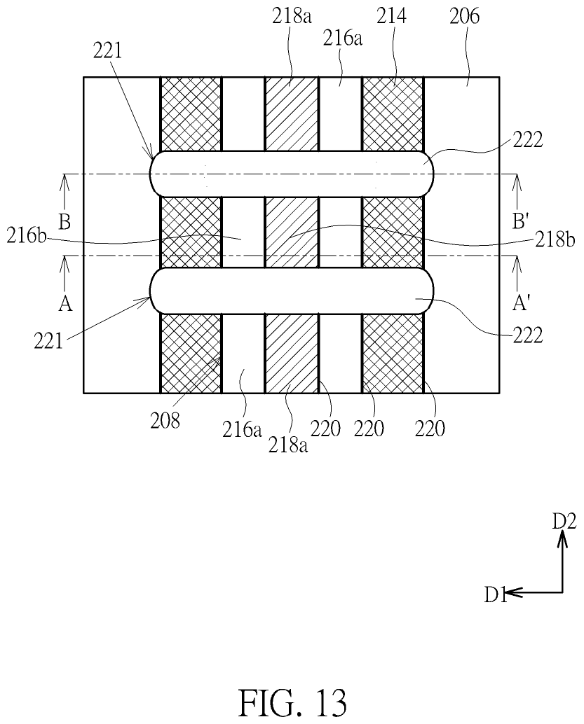

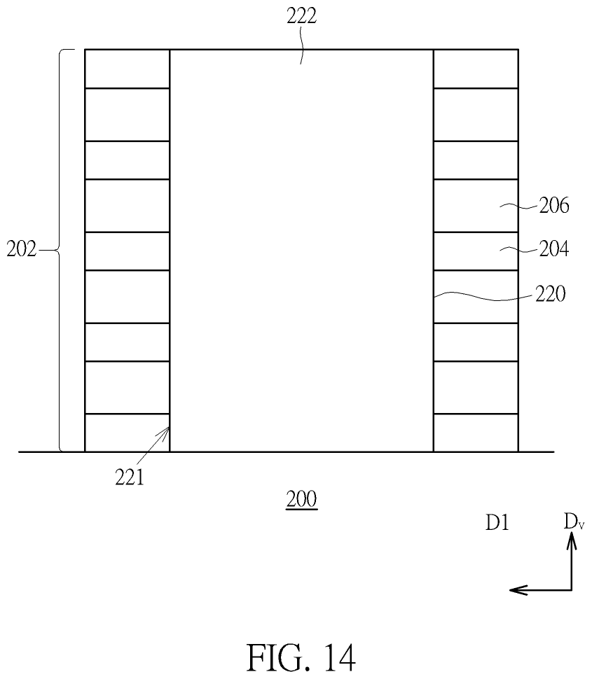

Thereafter, please refer collectively to FIG. 13 and FIG. 14, wherein FIG. 13 is a schematic top view of a 3D phase change memory in accordance with this embodiment of present invention, and FIG. 14 is a schematic cross-sectional view taken along the section line B-B′ in FIG. 13. Previous FIG. 12 is the schematic cross-sectional view taken along the section line A-A′ in FIG. 13. After the OTS layers 214, the phase change layers 216 and the bottom electrodes 218 are formed, a photolithography process is then performed to form multiple holes 221 in the layer stack 202. The holes 221 extend in the vertical direction D_{V} from the substrate 200 to the surface of layer stack 202 through parts of the phase change layers 216 and bottom electrodes 218, and these holes 221 also extend in the first direction D1 to the second layers 206 at two sides through OTS layers 214. In this way, the holes 221 divide original phase change layer 216 and bottom electrode 218 into multiple phase change layers 216a, 216b and multiple bottom electrodes 218a, 218b, wherein the phase change layers 216a, 216b are odd memory units and even memory units of the 3D phase change memory respectively, while the bottom electrodes 218a, 218b are odd bit lines and even bit lines of the 3D phase change memory respectively. In addition, the holes 221 may be further filled with insulating material, ex. silicon oxide, to form isolation structures 222 for isolating the bottom electrodes 218a, 218b and the phase change layers 216a, 216b.

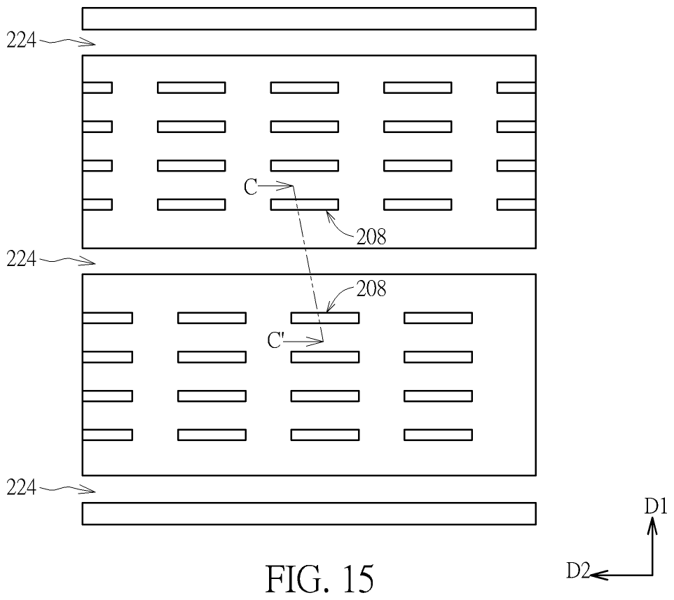

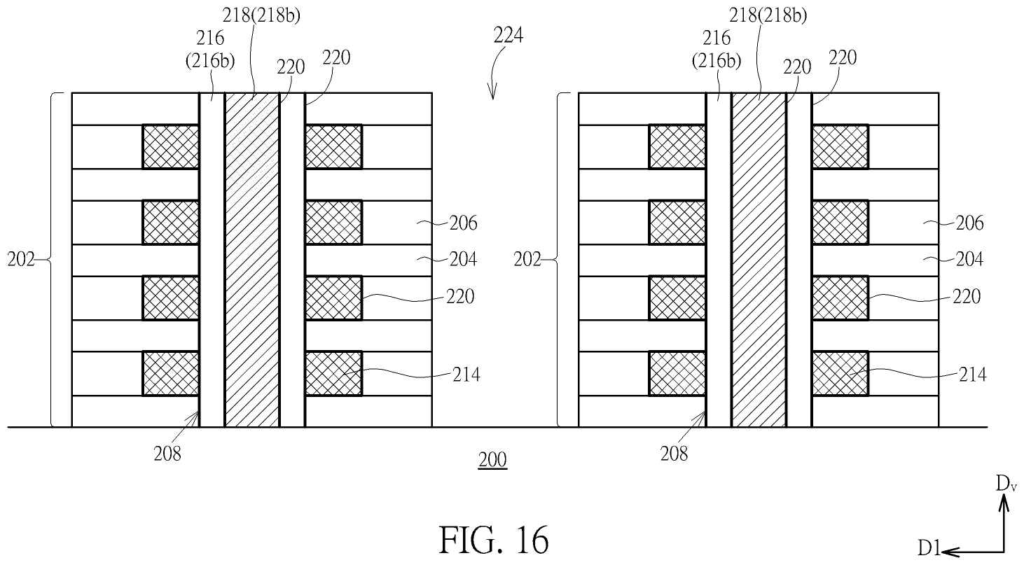

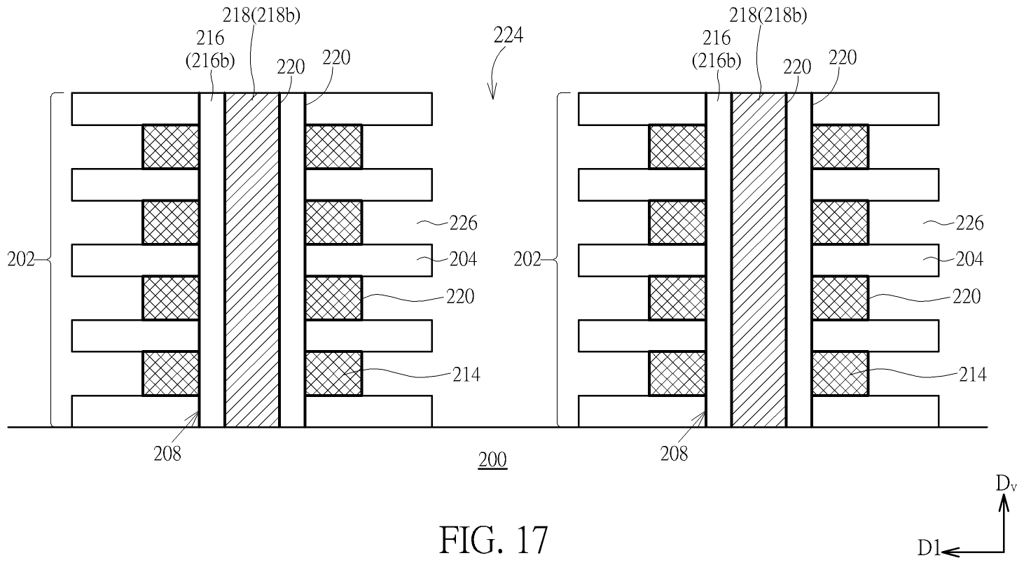

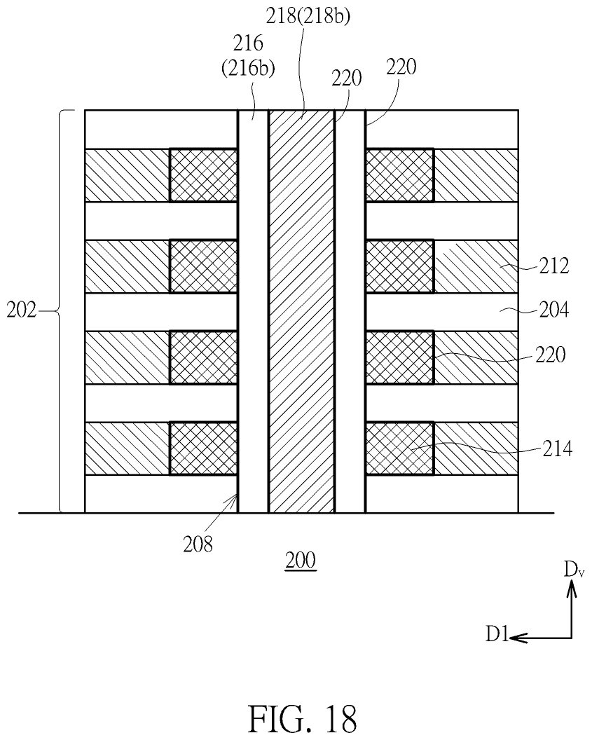

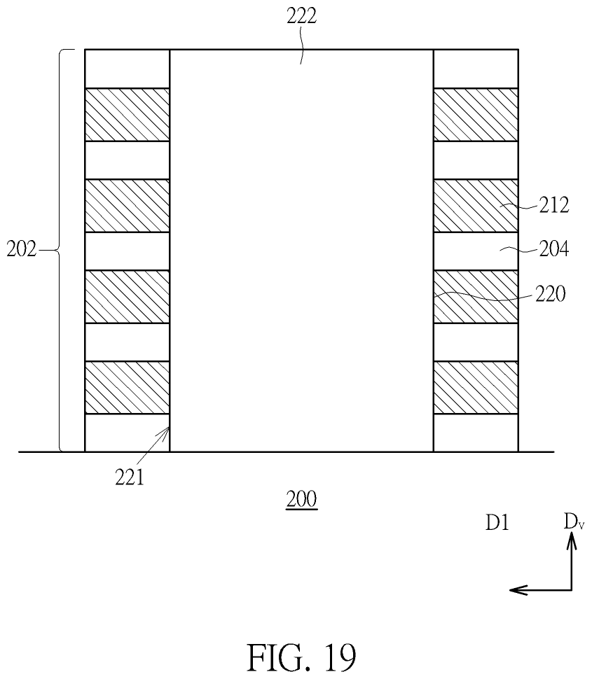

After the isolation structures 222 are formed, an etching process is then performed to remove the second layers 206 in the layer stack 202. Please refer to FIG. 15 to FIG. 17 for steps of the etching process, wherein FIG. 15 is a schematic top view of the 3D phase change memory in accordance with this embodiment, and FIG. 16 and FIG. 17 are schematic cross-sectional views taken along the section line C-C′ in FIG. 15.

First, as shown in FIG. 15 and FIG. 16, a photolithography process is performed to form a trench 224 in the layer stack 202 between the trenches 208 (i.e. structures like bottom electrodes 218, phase change layers 216, heating layer 220 formed in previous process). The trench 224 extend to the substrate 200 through every first layer 204 and second layer 206 in entire layer stack 202. In top views, the trench 224 extends through multiple trenches 208 (i.e. memory units) in the second direction D2. In the first direction D1, the space between trenches 224 may include multiple trenches 208, like four trenches 208 in a set between the trenches 224 as shown in the FIG. 15, depending on the design of product.

After the trenches 224 are formed, as shown in FIG. 15 and FIG. 17, a selective etching process is performed to completely remove the second layers 206 exposed from the trenches 224, while the first layers 204 are not removed in this process, thereby forming the lateral recesses 226 defined by the first layers 204 and the OTS layers 214. The lateral recesses 226 are recessed from the trench 224 in the horizontal first direction D1 and are alternated with the first layers 204 in the different levels of layer stack 202. Lastly, please refer to FIG. 18 and FIG. 19, which are schematic cross-sectional views taken respectively along section lines A-A′ and B-B′ in FIG. 8. After the second layers 206 are removed, the lateral recesses 226 are filled up with metal material like W, Cu, Al or the alloy thereof through ALD, thereby forming the top electrode layers 212. The top electrode layers 212 formed in this process would contact the OTS layers 214 in the layer stack 202 to constitute the final structure of present invention. In this embodiment, all original second layers 206 in layer stack 202 are replaced with the top electrode layers 212, so that parasite capacitance may be effectively reduced in the structure of device and make it more suitable for the memory architecture with high storage density.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A 3D phase change memory, comprising:
a substrate;
a layer stack on said substrate and consisted of multiple alternate first layers and second layers;
a trench extending from said substrate in a direction vertical to said substrate through entire said layer stack, and each said second layer is recessed in a horizontal first direction from said trench to form a lateral recess;
multiple adhesive layers, each said adhesive layer is on a surface of one said lateral recess;
multiple top electrodes, each said top electrode is on one said adhesive layer and fills up one said lateral recess;
two ovonic threshold switch (OTS) layers respectively on two sidewalls of said trench in said first direction;
multiple phase change layers on two sidewalls of said two OTS layers in said first direction;
multiple bottom electrodes between said phase change layers and filling up said trench; and
multiple holes vertically extending to a surface of said layer stack from said substrate, wherein said holes divide said bottom electrodes in a horizontal second direction and divide said phase change layers in said second direction, wherein said second direction is perpendicular to said first direction.

2. The 3D phase change memory of claim 1, further comprising heating layers between said top electrodes and said two OTS layers, or between said two OTS layers and said phase change layers, or between said phase change layers and said bottom electrodes.

3. The 3D phase change memory of claim 1, wherein said holes are filled up with silicon oxide to form isolating structures, and said isolating structures isolate said bottom electrodes and isolate said phase change layers.

4. The 3D phase change memory of claim 1, wherein lateral surfaces of said top electrodes, said adhesive layers and said first layers in said first direction are flush.

5. The 3D phase change memory of claim 1, wherein said top electrodes are word lines, and said trench and said word lines extend in said second direction, and said bottom electrodes are odd bit lines and even bit lines extending from said substrate to said surface of said layer stack in said vertical direction, and said odd bit lines and said even bit lines are alternated in said second direction.

6. A 3D phase change memory, comprising:
a substrate;
a layer stack on said substrate and consisted of multiple alternate first layers and top electrode layers;
a trench extending from said substrate through entire said layer stack in a direction vertical to said substrate, and each said top electrode layer is recessed in a horizontal first direction from said trench to form a lateral recess;
multiple ovonic threshold switch (OTS) layers, each said OTS layer fills up one said lateral recess;
multiple phase change layers on sidewalls of said trench in said first direction;
multiple bottom electrodes between said phase change layers and filling up said trench; and
multiple holes extending to a surface of said layer stack from said substrate in said vertical direction, wherein said holes divide said bottom electrodes in a horizontal second direction and divide said phase change layers in said second direction, wherein said second direction is perpendicular to said first direction.

7. The 3D phase change memory of claim 6, further comprising heating layers between said top electrodes and said OTS layers, or between said OTS layers and said phase change layers, or between said phase change layers and said bottom electrodes.

8. The 3D phase change memory of claim 6, wherein said holes are filled up with silicon oxide to form isolating structures, and said isolating structures isolate said bottom electrodes and isolate said phase change layers.

9. The 3D phase change memory of claim 6, wherein lateral surfaces of said OTS layers and said first layers in said first direction are flush.

10. The 3D phase change memory of claim 6, wherein said top electrodes are word lines, and said trench, said OTS layers and said word lines extend in said second direction, and said bottom electrodes are odd bit lines and even bit lines extending from said substrate to said surface of said layer stack in said vertical direction, and said odd bit lines and said even bit lines are alternated in said second direction.
